(19) United States
(12) Patent Application Publication
(10) Pub. No.: US 2002/0192948 A1
(43) Pub. Date: Dec. 19, 2002

(54) Integrated barrier layer structure for copper contact level metallization

(75) Inventors: Fusen Chen, Saratoga, CA (US); Ling Chen, Sunnyvale, CA (US); Gongda Yao, Fremont, CA (US); Ming Xi, Milpitas, CA (US); Barry Chin, Saratoga, CA (US); Mei Chang, Saratoga, CA (US); Seshadri Ganguli, Sunnyvale, CA (US); Michael X. Yang, Palo Alto, CA (US); Hyungsuk Alexander Yoon, Santa Clara, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/882,696

(22) Filed: Jun. 15, 2001

(51) Int. Cl. H01L 21/4763; H01L 21/44

(52) U.S. Cl. 438/643; 438/648; 438/653; 438/656

(57) ABSTRACT

A method of forming a composite barrier layer structure for use in integrated circuits is disclosed. The composite barrier layer structure formed using both physical vapor deposition (PVD) and chemical vapor deposition (CVD) techniques. The composite barrier layer structure comprises a CVD deposited layer formed on a PVD deposited layer. During the PVD process, the underlying surface of the substrate is treated, reducing the resistivity of the barrier layer structure formed thereon.

### BACKGROUND OF THE DISCLOSURE

1. Field of the Invention

The present invention relates to contact level metallization processes and, more particularly to barrier layers suited for contact level metallization processes.

2. Description of the Background Art

Sub-quarter micron multi-level metallization is one of the key technologies for the next generation of integrated circuits. Multi-level interconnects are formed in high aspect ratio features such as, for example, contacts and vias. Reliable formation of interconnect features is important to the production of integrated circuits as well as the continued efforts to increase circuit density.

A typical process for forming interconnect features on integrated circuits includes depositing one or more material layers on a substrate, defining one or more interconnect features in the material layers, depositing a barrier layer in the features, and finally filling the features with a conductive material. In some applications, the features are formed in a dielectric material disposed between a lower conductive layer and an upper conductive layer. The interconnect features are formed in the dielectric material with conductive material to link the lower conductive layer to the upper conductive layer.

The interconnect features are typically formed using physical vapor deposition (PVD) and/or chemical vapor deposition (CVD) techniques. For example, barrier material may be sputtered from a target to deposit a barrier layer on the substrate using PVD. However, as the dimensions of integrated circuit features are reduced (e. g., integrated circuit dimensions less than about 0.2 μm (micrometers)) the step coverage of PVD deposited films may be poor. The step coverage of a film is a measure of how well such film maintains its nominal thickness as it crosses steps that occur on the surface of the substrate. Step coverage is expressed as the ratio of the minimum thickness of a film as it crosses a step to the nominal thickness of the film on flat regions.

CVD films may be formed by thermally decomposing a precursor gas or by reacting one or more precursor gases. However, while CVD process form films with good step coverage, such films typically have high resistivities (e. g., resistivities greater than about 100,000 μΩ-cm) which can produce interconnect features with higher resistances than the design parameters may allow for many integrated circuits.

Therefore, a need exists in the art for a method of forming films for interconnect features with good step coverage and low resistivities.

### SUMMARY OF THE INVENTION

A method of forming a composite barrier layer structure for use in integrated circuits is provided. The composite barrier layer structure formed using both physical vapor deposition (PVD) and chemical vapor deposition (CVD) techniques. The composite barrier layer structure comprises a CVD deposited layer formed on a PVD deposited layer. During the PVD process, the underlying surface of the substrate is treated, reducing the resistivity of the barrier layer structure formed thereon.

The composite barrier layer is compatible with integrated circuit fabrication processes such as, for example interconnect features. For such an integrated circuit fabrication process, a preferred process sequence includes providing a substrate having a dielectric material formed on a conductive material. The dielectric material has interconnect features formed therein. A composite barrier layer structure comprising a CVD deposited layer formed on a PVD deposited layer is formed in the interconnect features. After the composite barrier layer structure is formed, the interconnect feature is completed by filling such structure with a conductive material.

### BRIEF DESCRIPTION OF DRAWINGS

The teachings of the present invention can be readily understood by considering the following detailed description in conjunction with the accompanying drawings, in which:

FIG. 1 depicts a schematic cross-sectional view of interconnect features formed on a substrate;

FIG. 2 shows a flow chart of a process sequence for forming the interconnect features depicted in FIG. 1;

FIG. 3 depicts a schematic illustration of an a physical vapor deposition (PVD) chamber that can be used for the practice of embodiments described herein;

FIG. 4 is a schematic illustration of a chemical vapor deposition (CVD) chamber that can be used for the practice of embodiments described herein;

FIG. 5 is a schematic illustration of a cluster tool including a PVD chamber and a CVD chamber; and

FIG. 6 is a schematic hierarchical diagram of a computer program that can be used to operate the cluster tool shown in FIG. 5.

### DETAILED DESCRIPTION

A method of forming a composite barrier layer structure for use in integrated circuits is provided. The composite barrier layer structure formed using both physical vapor deposition (PVD) and chemical vapor deposition (CVD) techniques. The composite barrier layer structure comprises a CVD deposited layer formed on a PVD deposited layer. During the PVD process, the underlying surface of the substrate is treated, reducing the resistivity of the barrier layer structure formed thereon.

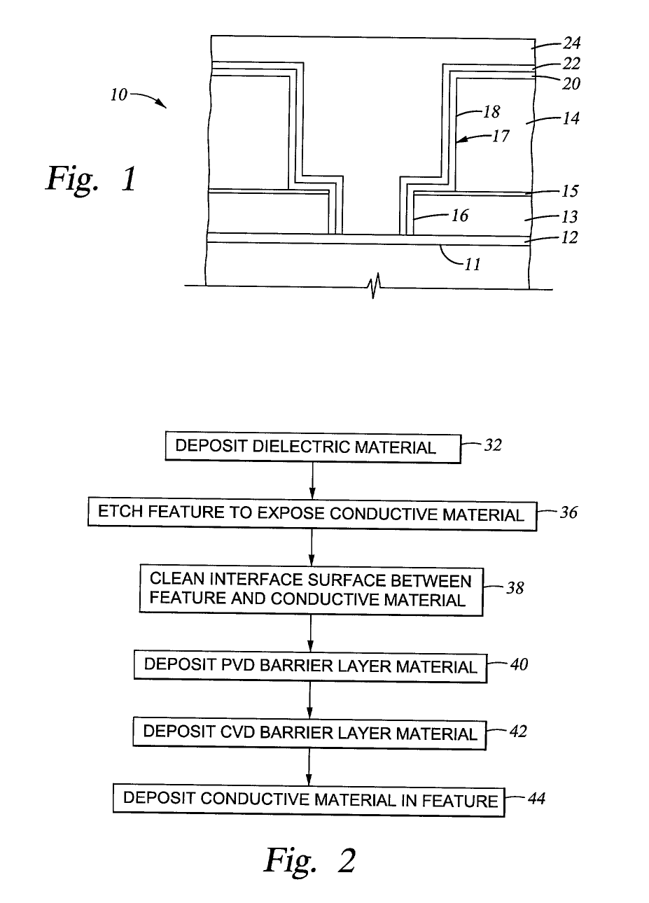

The formation of the composite barrier layer structure will be described below with reference to FIG. 1. FIG. 1 is a schematic cross-sectional view of interconnect feature 10 formed in dielectric layers deposited on a substrate. In one embodiment, a stack of dielectric layers 13, 14, 15 are formed on a conductive metal layer 12 on a surface 11 of a substrate. Generally, the conductive metal layer may be formed of copper (Cu), aluminum (Al), tungsten (W), gold (Au), and alloys thereof, among others.

The dielectric layers 13, 14 may be formed of a material such as, for example, silicon oxide, doped silicon oxides such as fluorinated silicon glass (FSG), boron phosphate silicon glass (BPSG), carbon-doped silicon oxides, silicon oxynitrides, and other low dielectric constant (low k) materials. The dielectric layers 13, 14 preferably have a dielectric constant of less than about 4.0, to improve device performance.

Additionally, an etch stop 15 may separate the dielectric layers 13, 14. The etch stop 15 is used to define the interconnect features in the dielectric layers 13,14. An interconnect feature 17 is defined in the dielectric layers 13, 14, 15 to expose a portion of the conductive metal layer 12.

A physical vapor deposited (PVD) barrier layer 20 is deposited over dielectric layer 14 and exposed portions of the conductive metal layer 12 at the bottom of the interconnect feature 17. The PVD barrier layer 20 may be deposited in a PVD chamber, such as, for example, the chamber depicted in FIG. 3. The PVD deposited barrier layer 20 may be formed of tantalum (Ta), tantalum nitride (TaN), or a combination of Ta with TaN as a bilayer or TaN with a Ta layer deposited thereon. Other suitable materials may include, for example, tungsten (W), tungsten nitride (WₓN), titanium (Ti), titanium nitride (TiN) and any other conventional refractory metals in pure form, alloys, or nitrides thereof. The PVD deposited barrier layer 20 preferably has a thickness of less than about 200 Å, and is typically about 50 Å to about 150 Å thick.

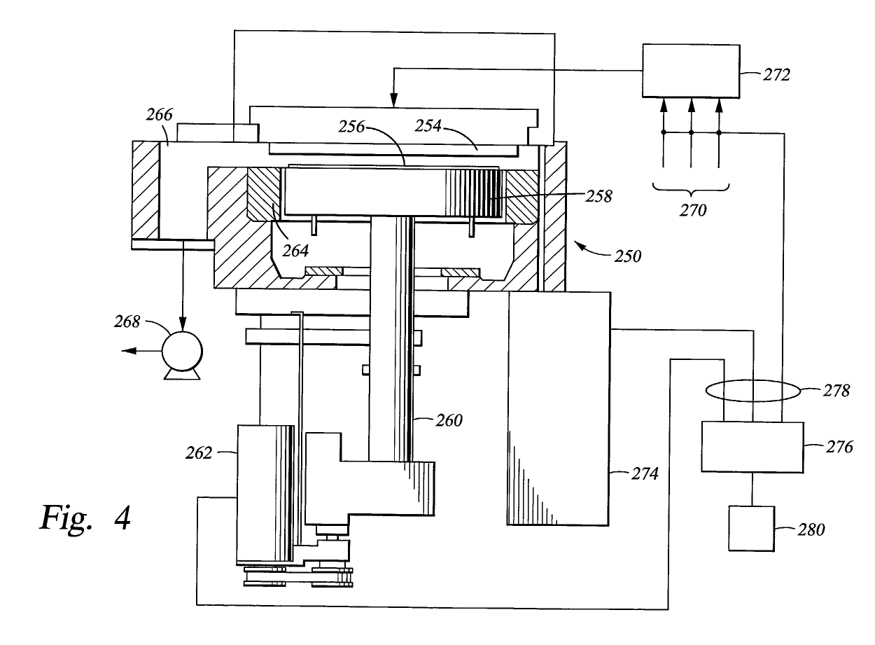

A chemical vapor deposited (CVD) barrier layer 22 is deposited on the PVD deposited barrier layer 20. The CVD deposited barrier layer 22 is also a relatively thin layer, having for example, a thickness of less than about 100 Å, and typically about 10 Å to about 50 Å thick. The CVD deposited barrier layer 22 may be performed in a CVD chamber, such as, for example, the chamber depicted in FIG. 4. The CVD deposited barrier layer provides a generally conformal layer along the sidewalls of the interconnect structure 17 defined in the dielectric layers 13, 14,15. The combination of the PVD deposited layer 20 with the CVD deposited layer 22 provides better low resistivity contacts to the conductive metal layer 12.

The CVD deposited barrier layer 22 may be formed of tantalum (Ta), tantalum nitride (TaN), or a combination of Ta with TaN as a bilayer or TaN with a Ta layer deposited thereon. Other suitable materials may include, for example, tungsten nitride (WₓN) or bilayers of tungsten (W) followed by WₓN or WₓN followed by W, TiN, titanium silicon nitride (TiNSi), or and any other conventional refractory metals in pure form, alloys, or nitrides thereof.

A conductive layer 24 is deposited over the CVD deposited barrier layer 22. The conductor may be comprised of copper (Cu), aluminum (Al), tungsten (W), and combinations thereof, among other materials. The conductive layer 24 may be deposited utilizing a variety of deposition methods including PVD, CVD, electroplating and combinations thereof.

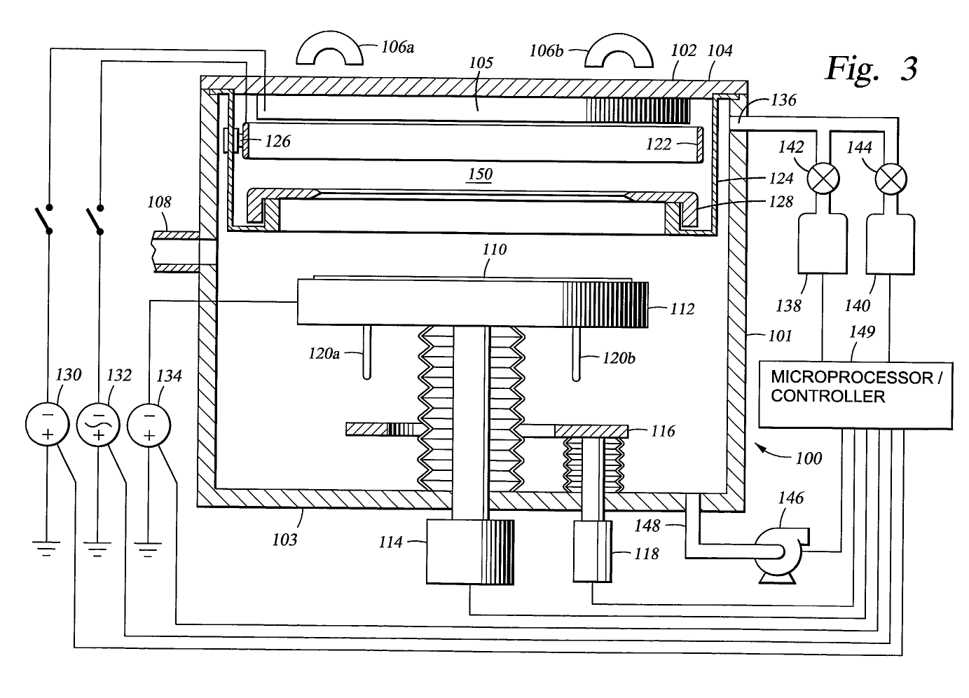

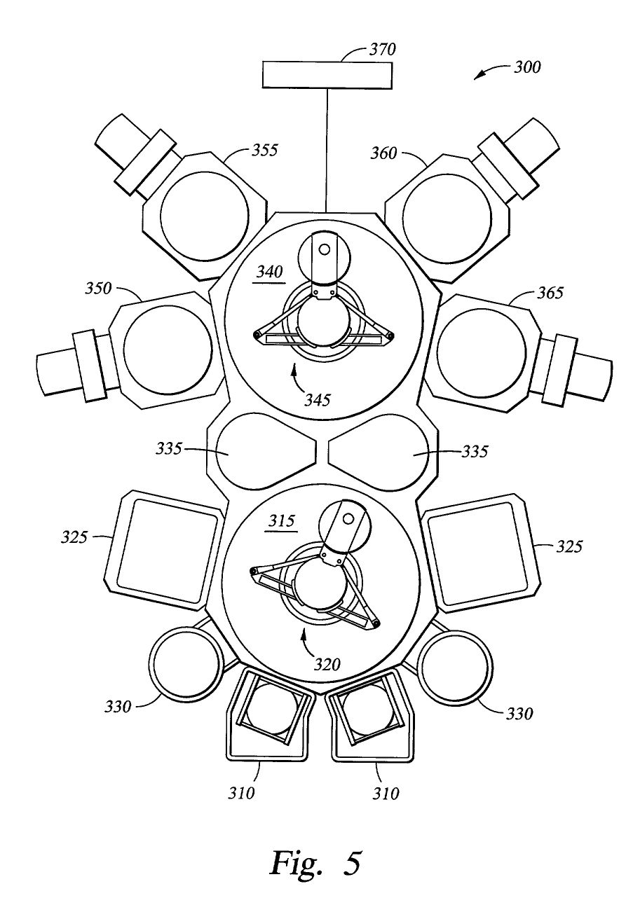

FIG. 2 depicts a flowchart showing one suitable process sequence for depositing the composite barrier layer. The steps shown in FIG. 2 can be executed in response to instructions from a computer program executed by, for example, a microprocessor or computer controller 370, shown in FIG. 5.

Dielectric layers 13,14 are deposited over a conductive metal layer 12 at step 32. The dielectric layers 13, 14 are etched to define an interconnect feature in step 36. If an etch stop 15 is present, the etch stop 15 may be used to define the interconnect feature through the dielectric layers 13, 14. The etch process may be performed in an etch chamber, such as the etch chamber 355 shown in the cluster tool system 300 of FIG. 5. One example of a suitable etch chamber is an IPS (Inductive Plasma Source) reactor commercially available from Applied Materials, Inc. of Santa Clara, Calif.

The surface of dielectric layer 14 as well as the surface of the conductive metal layer 12 may be pre-cleaned, as detailed in step 38, for example, by using a plasma such as a hydrogen plasma prior to forming the PVD deposited barrier layer 20 thereon. The plasma is believed to remove loosely bonded atoms from the surfaces of both the dielectric material and the conductive metal layer. The pre-cleaning process can be carried out in a variety of processing chambers, such as, for example a Pre-Clean II Chamber commercially available from Applied Materials, Inc., Santa Clara, Calif.

Other processing chambers may also be used for the pre-clean process, such as, for example, a PVD chamber, a CVD chamber or an etch chamber. In particular, the pre-cleaning process can be carried out in the same PVD chamber used to form the PVD deposited barrier layer.

Referring to step 40, a PVD deposited barrier layer 20 is formed on the pre-cleaned surface of the conductive metal layer 12 and the dielectric layer 14. A PVD chamber used for forming the PVD deposited barrier layer in an exemplary embodiment can be a part of an integrated system, such as one described with reference to FIG. 5. An exemplary process regime for forming the PVD deposited barrier layer 20 is described below in “Exemplary Process.”

A CVD deposited barrier layer 22 is formed over the PVD deposited barrier layer 20 to create the composite barrier layer, as described in step 42. A CVD chamber used for forming the CVD deposited barrier layer in an exemplary embodiment can be a part of an integrated system, such as one described with reference to FIG. 5. An exemplary process regime for forming the CVD deposited barrier layer 22 is described below in “Exemplary Process.”

Both the PVD deposited barrier layer 20 as well as the CVD deposited barrier layer 22 may be formed in an integrated system, i.e., in-situ, so vacuum is not substantially broken and little or no exposure to contamination occurs between the PVD and the CVD processes. Thus, the interface between the PVD deposited barrier layer 20 and CVD deposited barrier layer 22 has a low resistivity.

A conductive layer 24 is formed over the CVD deposited barrier layer to fill the interconnect structure, as described in step 44. The conductive layer is formed of a conductive material and can be deposited by PVD, CVD, electroplating, and combinations thereof. In some embodiments, the conductive layer can be deposited as a fill layer, and in other embodiments, the conductive layer can include a seed layer upon which a fill layer is grown, such as in electroplating.

### Exemplary Process

One exemplary process for forming the PVD deposited barrier layer is discussed herein with reference to a TaN barrier material. It is to be understood, however, that the process is only exemplary and other materials can be deposited. An integrated system such as an Endura® system available from Applied Materials, having a pre-clean chamber, an etch chamber, a CVD chamber and a PVD chamber, as shown in FIG. 5 may be used. In general, the following deposition process parameters can be used to form the PVD deposited barrier layer in a PVD chamber similar to that shown in FIG. 3. The process parameters range from a target power of about 20 W/cm² to about 600 w/cm², a coil power of about 50 W/cm² to about 250 W/cm², an inert gas flow rate of about 10 sccm to about 2000 sccm, a nitrogen (N₂) flow rate of about 5 sccm to about 1500 sccm, a chamber temperature of about 50° C. to about 450° C. and a chamber pressure of about 5 mtorr to about 100 mTorr. The substrate is optionally biased within a range of about 0 W to about 600 W for about half of the deposition cycle.

In general, the following process parameters may be used for forming a CVD deposited barrier layer of for example, TiNSi, over the PVD deposited barrier layer in a CVD chamber similar to that shown in FIG. 4. The process parameters range from a chamber pressure of about 0.5 Torr to about 10 Torr, a chamber temperature of about 100° C. to about 400° C., and precursor (TDMAT and SiH₄) flow rates of about 10 sccm to about 1000 sccm.

Other deposition chambers are within the scope of the invention, and the parameters listed above may vary according to the particular deposition chamber used to form the composite barrier layer. For example, other deposition chambers may have a larger or smaller volume, requiring gas flow rates that are larger or smaller than those recited for deposition chambers available from Applied Materials, Inc.

The resistivity of composite barrier layers deposited using the above exemplary processes were compared to a typical TiNSi barrier layer deposited by CVD alone. Test results indicate that the composite barrier layers deposited by PVD and then by CVD had a resistivity of about 1 ohm-cm (normalized) compared to a resistivity of about 1.7 ohm-cm (normalized) for the CVD TiNSi specimen, providing a decrease in resistivity of about 41%. It is believed that the PVD process, which bombards the deposition surface with atoms/ions, assists in cleaning the interface between the exposed underlying conductor layer and a feature, while the barrier layer deposited by CVD provides good conformal coverage. The combined processes create a multistep conformal barrier layer having a low resistance.

### System Equipment

Methods according to the invention can be performed by providing process subroutines which are carried out in conventional PVD and CVD chamber systems.

### PVD-IMP Chamber

In some PVD processes, the sputtered material is ionized prior to being sputter deposited on the substrate, such as in an ionized metal plasma (IMP) process. One example of a chamber incorporating the IMP process is known as an IMP VECTRA™ chamber, available from Applied Materials, Inc. Generally, IMP is an extension of PVD technology that offers the benefit of highly directional deposition with good bottom coverage on high aspect ratio structures. In general, a coil is mounted between a substrate support and a target and provides inductively-coupled magnetic fields in the chamber to assist in generating and maintaining a plasma between the target and substrate. Power supplied to the coil densifies the plasma which ionizes the sputtered material. An electric field, or self-bias, develops in the boundary layer, or sheath, between the plasma and the substrate that accelerates the metal ions towards the substrate in a vector perpendicular to the substrate surface. The ionized material is directed toward the substrate and deposited thereon. The bias energy can be modulated on the substrate by an optional application of power, such as RF power. Because of the highly directional nature of the ions, the bottom coverage is substantially unaffected by feature width. PVD-IMP technology and other types of PVD technologies are included within the term PVD as used herein.

FIG. 3 is a schematic cross-sectional view of an exemplary IMP chamber 100, such as a VECTRA™ chamber, in which the invention may be used to advantage. The IMP chamber can be integrated into an Endura® platform, also available from Applied Materials, Inc. The chamber 100 includes sidewalls 101, lid 102, and bottom 103. The lid 102 includes a target backing plate 104, which supports a target 105 of the material to be deposited.

An opening 108 in the chamber 100 provides access for a robot (not shown) to deliver and retrieve substrates 110 to and from the chamber 100. A substrate support 112 supports the substrate 110 and is typically grounded.

The substrate support 112 is mounted on a lift motor 114 that raises and lowers the substrate support 112 and a substrate 110 disposed thereon. A lift plate 116 connected to a lift motor 118 is mounted in the chamber 100 and raises and lowers pins 120a, 120b mounted in the substrate support 112. The pins 120a, 120b raise and lower the substrate 110 from and to the surface of the substrate support 112.

A coil 122 is mounted between the substrate support 112 and the target 105 and provides inductively-coupled magnetic fields in the chamber 100 to assist in generating and maintaining a plasma between the target 105 and substrate 110. Power supplied to the coil 122 densifies the plasma which ionizes the sputtered material. The ionized material is then directed toward the substrate 110 and deposited thereon.

A shield 124 is disposed in the chamber 100 to shield the chamber sidewalls 101 from the sputtered material. The shield 124 also supports the coil 122 by supports 126. The supports 126 electrically insulate the coil 122 from the shield 124 and the chamber 100. The clamp ring 128 is mounted between the coil 122 and the substrate support 112 and shields an outer edge and backside of the substrate from sputtered materials when the substrate is raised into a processing position to engage the lower portion of the clamp ring. In some chamber configurations, the shield 124 supports the clamp ring 128 when the substrate 110 is lowered below the shield 124 to enable substrate transfer.

Three power supplies are used in this type of inductively coupled sputtering chamber. Power supply 130 delivers preferably DC power for conductive materials to the target 105 to cause the processing gas to form a plasma. Magnets 106a, 106b disposed behind the target backing plate 104 increase the density of electrons adjacent to the target 105, thus increasing ionization at the target to increase the sputtering efficiency, by generating magnetic field lines generally parallel to the face of the target, around which electrons are trapped in spinning orbits to increase the likelihood of a collision with, and ionization of, a gas atom for sputtering. Power source 132, preferably a RF power source, supplies electrical power at about 13.56 mHz to the coil 122 to increase the density of the plasma. Power source 134, typically a DC power source, biases the substrate support 112 with respect to the plasma and provides directional attraction of the ionized sputtered material toward the substrate 110.

Processing gas, such as an inert gas of argon or helium, is supplied to the chamber 100 through a gas inlet 136 from gas sources 138, 140 as metered by respective mass flow controllers 142, 144. The processing gas is introduced into a process cavity 150, defined by the target 105, the substrate 110 disposed on the substrate support 112 in the processing position and the upper shield 124. A vacuum pump 146 is connected to the chamber 100 at an exhaust port 148 to exhaust the chamber 100 and maintain the desired pressure in the chamber 100.

A controller 149 controls the functions of the power supplies, lift motors, mass flow controllers for gas injection, vacuum pump, and other associated chamber components and functions. The controller 149 executes system control software stored in a memory, which in the preferred embodiment is a hard disk drive, and can include analog and digital input/output boards, interface boards, and stepper motor controller boards (not shown). Optical and/or magnetic sensors (not shown) are generally used to move and determine the position of movable mechanical assemblies.

In operation, a robot (not shown) delivers a substrate 110 to the chamber 100 through the opening 108. The pins 120a, 120b are extended upward, lift the substrate 110 from the robot, and the robot retracts from the chamber 100. The pins 120a, 120b lower the substrate 110 to the surface of the substrate support 112. The substrate support 112 raises the substrate 110 to engage the clamp ring 128. A processing gas is injected into the chamber 100 and a plasma is generated between the target 105 and the substrate support 112 with power from the power source 130. The power source 132 delivers power to the coil, which densifies the plasma and ionizes the sputtered target material leaving the target 105 to form sputtered material ions. The sputtered material ions are accelerated toward the biased substrate 110. The process pressure may be operated from about 5 to about 100 mTorr to increase the ionization probability of the sputtered material atoms as the atoms travel through the plasma region.

After deposition, the substrate support is lowered, the pins 120a, 120b are raised to lift the substrate 110, a robot (not shown) enters the chamber 100, retrieves the substrate 110, and if desired, delivers another substrate for processing.

### CVD Chamber

FIG. 4 is a schematic cross section view of an exemplary CVD chamber 250. One suitable CVD plasma reactor in which a CVD layer can be deposited is a TXZ™ chamber, also available from Applied Materials, Inc. Chamber 250 contains a gas distribution manifold 254 for dispersing process gases through perforated holes (not shown) in the manifold to a substrate 256 that rests on a substrate support plate or susceptor 258.

Susceptor 258 is resistively heated and mounted on a support stem 260, so that susceptor 258 (and the substrate 256 supported on the upper surface of susceptor 258) can be controllably moved by a lift motor 262 between a lower loading/off-loading position and an upper processing position which is closely adjacent to the manifold 254. The susceptor 258 and the substrate 256 are surrounded by a ring 264. During processing, gases inlet to manifold 254 are uniformly distributed radially across the surface of the substrate 256. The gases exhaust through a port 266 by a vacuum pump system 268 having a throttle valve (not shown) to control an exhaust rate of gas from the chamber 250.

Before reaching manifold 254, deposition and carrier gases are input through gas supply lines 270 into a mixing system 272, combined and then sent to manifold 254. Generally, the process gas supply lines 270 for each of the process gases include i) safety shut-off valves (not shown) that can be used to automatically or manually shut off the flow of process gas into the chamber 250, and ii) mass flow controllers (also not shown) that measure the flow of gas through the gas supply lines 270. When toxic gases are used in the process, several safety shut-off valves are positioned on each gas supply line in conventional configurations.

In a plasma enhanced CVD process, a controlled plasma is formed adjacent to the substrate 256 by RF energy applied to the manifold 254 from RF power supply 274 (with susceptor 258 grounded). Gas distribution manifold 254 is also an RF electrode, while susceptor 258 is grounded. RF power supply 274 can supply either single or mixed frequency RF power to manifold 254 to enhance the decomposition of reactive species introduced into chamber 250. A mixed frequency RF power supply typically supplies power at a high RF frequency (RF1) of 13.56 MHz and at a low RF frequency (RF2) of 350 kHz.

Heat is provided to the susceptor 258 by a resistive heat coil embedded in the susceptor 258. This additional heat compensates for the natural heat loss of the susceptor and provides rapid and uniform susceptor and substrate heating for effecting deposition.

The lift motor 262, the gas mixing system 272, and the RF power supply 274 are controlled by a system controller 276 over control lines 278. The reactor includes analog assemblies such as mass flow controllers (MFCs), RF generators, and lamp magnet drivers that are controlled by the system controller 276 which executes system control software stored in a memory 280, preferably a hard disk drive. The computer program dictates the timing, mixture of gases, RF power levels, susceptor position, and other parameters of a particular process. Motors and optical sensors (not shown) are used to move and determine the position of movable mechanical assemblies, such as the throttle valve of the vacuum system 268 and motor for positioning the susceptor 258.

The system controller 276 controls all of the activities of the CVD reactor and one embodiment of the controller 276 includes a hard disk drive, a floppy disk drive, and a card rack (not shown). The card rack contains a single board computer (SBC), analog and digital input/output boards, interface boards and stepper motor controller boards. The system controller 276 conforms to the Versa Modular Europeans (VME) standard which defines board, card cage, bus structure, and connector dimensions and types.

Typically, any or all of the chamber lining, gas inlet manifold faceplate, support stem 260, and various other reactor hardware is made out of material such as aluminum or aluminum oxide. An example of such a CVD reactor is described in U.S. Pat. No. 5,000,113, entitled “Thermal CVD/PECVD Reactor and Use for Thermal Chemical Vapor Deposition of Silicon Dioxide and In-situ Multi-step Planarized Process,” issued to Wang et al., which is assigned to Applied Materials, Inc., the assignee of the present invention, and incorporated herein by reference.

### Cluster Tool

FIG. 5 is a schematic top view of a one embodiment of a processing system, known as a cluster tool. A cluster tool generally refers to a modular, multi-chamber, integrated processing system. Two examples of commercially available substrate processing platforms include an Endura® platform and a Centura® platform offered by Applied Materials, Inc. The cluster tool generally includes a central substrate handling vacuum chamber and a number of peripheral vacuum process chambers. The substrates go through a set of process steps under vacuum in the various process stations without being exposed to ambient conditions, i.e., in-situ. The transfer of the substrates for the processes is managed by a centralized robot in a substrate handling vacuum chamber, that is also maintained under vacuum conditions.

Different types of cluster tools, such as linear or radial, with different types of architecture are also possible and included within the definition of a cluster tool herein. The platform combines vacuum chambers designed to process substrates at low pressure/high vacuum generally in the range of 10⁻³ to 10⁻⁸ torr, although other ranges are possible. For example, the predegasing and heating of the substrate to bake out the moisture, the precleaning of the exposed surfaces with the plasma, the PVD deposition of the barrier layer, the CVD deposition of the barrier layer, and the subsequent conductive deposition in the feature could be performed in-situ within a single cluster tool. Such a system would help maintain the vacuum and cleanliness during the depositions to assist in providing low resistivities.

Substrate processing platforms generally include at least two load lock chambers mounted on separate openings to a central substrate handling vacuum chamber for loading or unloading substrates while the vacuum chamber remains under vacuum. Two chambers are usually required to maintain continuous operation such that substrates are processed from one load lock chamber while finished substrates are unloaded from the other chamber and new substrates are loaded.

Referring to FIG. 5, the processing system 300 generally includes a plurality of processing chambers, load lock chambers, and transfer chambers as well as robots. The system 300 is also equipped with a microprocessor/controller 370 programmed to control the various processing methods performed in the processing system 300. The cluster tool system 300 includes vacuum load-lock chambers 305 and 310 attached to a first stage transfer chamber 315. The load-lock chambers 305 and 310 maintain vacuum conditions within the first stage transfer chamber 315 while substrates enter and exit system 300. A first robot 320 transfers substrates between the load-lock chambers 305 and 310 and one or more substrate processing chambers 325 and 330 attached to the first stage transfer chamber 315.

Processing chambers 325 and 330 can be outfitted to perform a number of substrate processing operations such as CVD, PVD, etch, pre-clean, degas, orientation, anneal and other substrate processes. The first robot 320 also transfers substrates to/from one or more transfer chambers 335 disposed between the first stage transfer chamber 315 and a second stage transfer chamber 340.

The transfer chambers 335 are used to maintain ultrahigh vacuum conditions in the second stage transfer chamber 340 while allowing substrates to be transferred between the first stage transfer chamber 315 and the second stage transfer chamber 340. A second robot 345 transfers substrates between the transfer chambers 335 and a plurality of substrate processing chambers 350, 355, 360 and 365. Similar to processing chambers 325 and 330, the processing chambers 350 to 365 can be outfitted to perform a variety of substrate processing operations. For example, the processing chamber 350 is an etching chamber outfitted to etch apertures or openings for interconnect features; the processing chamber 355 is a PVD chamber outfitted to reactively sputter deposit a Ta or TaN film; the processing chamber 360 is a CVD chamber outfitted to deposit TiN or TiNSi; and the processing chamber 365 is a PVD chamber outfitted to sputter deposit a copper film.

The above listed sequence arrangement is one example of processing chambers useful for depositing layers described herein. A plurality of cluster tool systems may be required to perform all of the processes required to complete manufacturing of an integrated circuit or chip.

During operation, substrates are brought to vacuum load-lock chambers 305 and 310 by a conveyor belt or robot system (not shown) that operates under the control of a computer program executed by a microprocessor or computer 370. Also, the robots 320 and 345 operate under control of the computer program to transfer substrates between the various processing chambers of the cluster tool system 300.

The above-described cluster tool system is mainly for illustrative purposes. Other plasma processing equipment, such as electron cyclotron resonance (ECR) plasma processing devices, induction-coupled RF high-density plasma processing devices or the like may be employed as part of the cluster tool system.

### System Controller

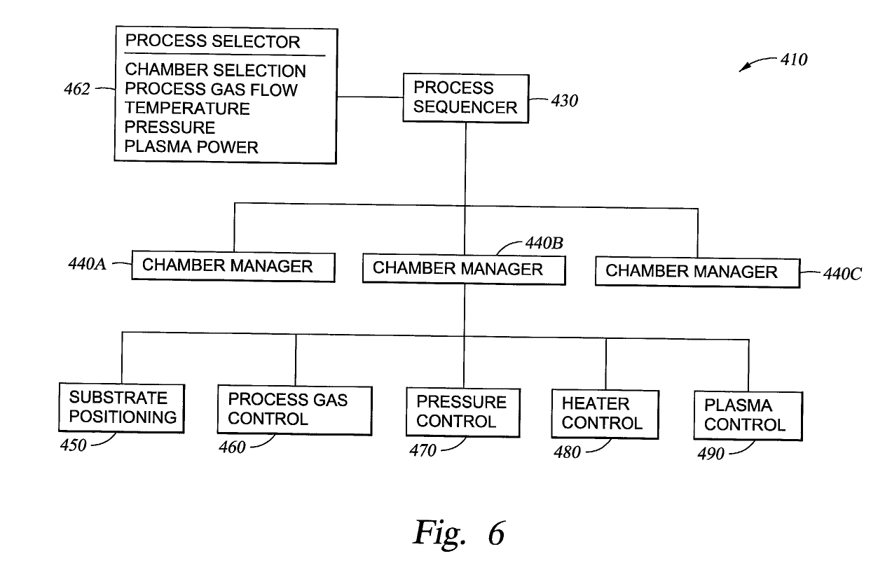

FIG. 6 is an illustrative block diagram of the hierarchical control structure of the computer program 410 used by the controller 370 shown in FIG. 5. A user enters a process set number and process chamber number into a process selector subroutine 462 in response to menus or screens displayed on the CRT monitor by using the light pen interface. Tile process sets are predetermined sets of process parameters necessary to carry out specified processes and are identified by predefined set numbers. Process selector subroutine 462 identifies (i) the desired process chamber in a multi-chamber system, and (ii) the desired set of process parameters needed to operate the process chamber for performing the desired process. The process parameters for performing a specific process relate to process conditions such as, for example, process gas composition and flow rates, temperature, pressure, plasma conditions such as RF power levels, and chamber dome temperature, and are provided to the user in the form of a recipe. The parameters specified by the recipe are entered utilizing a light pen/CRT monitor interface (not shown).

A process sequencer subroutine 430 comprises program code for accepting the identified process chamber and set of process parameters from the process selector subroutine 462, and for controlling operation of the various process chambers. Multiple users can enter process set numbers and process chamber numbers, or a user can enter multiple process set numbers and process chamber numbers, so the sequencer subroutine 430 operates to schedule the selected processes in the desired sequence. Preferably the sequencer subroutine 430 includes a program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling which process is to be executed, the sequencer subroutine 430 can be designed to take into consideration the present condition of the process chamber being used in comparison with the desired process conditions for a selected process, or the “age” of each particular user entered request, or any other relevant factor a system programmer desires to include for determining scheduling priorities.

Once the sequencer subroutine 430 determines which process chamber and process set combination is going to be executed next, the sequencer subroutine 430 causes execution of the process set by passing the particular process set parameters to the chamber manager subroutines 440A-C. The chamber manager subroutines 440A-C, control multiple processing tasks in the various chambers, such as PVD chamber 355 for a barrier layer, CVD chamber 360 for a barrier layer, and possibly other chambers, such as another PVD chamber 365 for layer deposition according to a process set determined by sequencer subroutine 430. For example, the chamber manager subroutine 440A comprises program code for controlling PVD process operations, within the described process chamber 355, shown in FIG. 4. One example of the various multi-chamber routines could include a conductive layer deposited over the substrate, a dielectric layer deposited over the conductive layer, a PVD barrier layer deposited over the dielectric layer, a CVD layer barrier deposited over the PVD layer and a conductive layer deposited over CVD layer.

The chamber manager subroutines 440A-C also controls execution of various chamber component subroutines or program code modules, which control operation of the chamber components necessary to carry out the selected process set. For example, the controller 370 can incorporate the function of multiple individual chamber controllers, such as controller 166 shown in FIG. 3 and controller 276 shown in FIG. 4. Examples of chamber component subroutines are substrate susceptor control positioning subroutine 450, process gas control subroutine 460, pressure control subroutine 460, heater control subroutine 480, and plasma control subroutine 490. Those having ordinary skill in the art will recognize that other chamber control subroutines can be included depending on what processes are desired to be performed in the various chambers. In operation, chamber manager subroutines 440A-C selectively schedules or calls the process component subroutines in accordance with the particular process set being executed. Scheduling by chamber manager subroutines 440A-C is performed in a manner similar to that used by sequencer subroutine 430 in scheduling which process chamber and process set to execute. Generally, chamber manager subroutines 440A-C include steps of monitoring the various chamber components, determining which components need to be operated based on the process parameters for the process set to be executed, and causing execution of a chamber component subroutine responsive to the monitoring and determining steps.

While foregoing is directed to the one embodiment of the present invention, other and further embodiments of the invention may be devised without departing from the basic scope thereof, and the scope thereof is determined by the claims that follow.

What is claimed is:

1. A method of forming a composite barrier layer on a substrate, comprising:
a) providing a substrate, having a first conductive layer and at least one dielectric layer thereon, wherein the at least one dielectric layer is formed on the first conductive layer;
b) defining a feature in the at least one dielectric layer to the surface of the first conductive layer;
c) forming a PVD deposited barrier layer in the feature, wherein the surface of the conductive layer is treated as the PVD barrier layer is deposited thereon; and
d) forming a CVD deposited barrier layer over the PVD deposited layer.

2. The method of claim 1, further comprising forming a second conductive layer on the CVD deposited barrier layer.

3. The method of claim 2 wherein the second conductive layer is formed using either of chemical vapor deposition (CVD), physical vapor deposition (PVD), electroplating, or combinations thereof.

4. The method of claim 1, further comprising forming both the PVD deposited barrier layer and the CVD deposited barrier layer without breaking vacuum.

5. The method of claim 1, further comprising cleaning the surface of the first conductive layer with a plasma prior to forming the PVD deposited barrier layer.

6. The method of claim 1 wherein either of the PVD or the CVD deposited barrier layers comprise tantalum (Ta), tantalum nitride (TaN), tungsten (W), tungsten nitride (WₓN), titanium (Ti), titanium nitride (TiN), titanium silicon nitride (TiNSi), or combinations thereof.

7. The method of claim 2 wherein either of the first or second conductive layers comprises copper (Cu), aluminum (Al), tungsten (W), gold (Au), or combinations thereof.

8. The method of claim 1 wherein the PVD deposited barrier layer is formed using a PVD-IMP process.

9. A system for forming a composite barrier layer on a substrate, comprising:
a) a physical vapor deposition (PVD) chamber;
b) a chemical vapor deposition (CVD) chamber;
c) a transfer chamber coupled to both the PVD and CVD chambers;
d) a vacuum source coupled to the PVD, CVD and transfer chambers; and
e) a controller programmed to control a layer deposition sequence, comprising:
i) forming a PVD deposited barrier layer on a substrate wherein the surface of the substrate is treated as the PVD barrier layer is deposited thereon; and
ii) forming a CVD deposited barrier layer on the PVD deposited barrier layer.

10. The system of claim 9 wherein the layer deposition sequence further comprises depositing a conductive layer on the CVD deposited barrier layer.

11. The system of claim 9, further comprising an etch chamber.

12. The system of claim 9 wherein the controller further comprises a program sequence to clean the substrate prior to forming the PVD deposited barrier layer thereon.

13. The system of claim 9 wherein either of the PVD and CVD deposited barrier layers comprise tantalum (Ta), tantalum nitride (TaN), tungsten (W), tungsten nitride (WₓN), titanium (Ti), titanium nitride (TiN), titanium silicon nitride (TiNSi) or combinations thereof.

14. The method of claim 10 wherein the conductive layer comprises copper (Cu), aluminum (Al), tungsten (W), gold (Au), or combinations thereof.

15. A conductive feature, comprising:
a) a physical vapor deposition (PVD) deposited barrier layer formed in a feature defined in one or more dielectric layers on a substrate, wherein the surface of the substrate is treated as the PVD barrier layer is deposited thereon;
b) a chemical vapor deposition (CVD) deposited barrier layer formed over the PVD deposited barrier; and
c) a conductive layer formed on the CVD deposited barrier layer.

16. The conductive feature of claim 15 wherein the conductive layer is formed using either of chemical vapor deposition (CVD), physical vapor deposition (PVD), electroplating, or combinations thereof.

17. The conductive feature of claim 15 wherein both the PVD deposited barrier layer and the CVD deposited barrier layer are formed without breaking vacuum.

18. The conductive feature of claim 15 wherein either of the PVD and the CVD deposited barrier layers comprise Ta, TaN, Ta/TaN, TaN/Ta, W, WₓN, Ti and TiN or combinations thereof.
